(19) United States
(12) Patent Application Publication
(10) Pub. No.: US 2026/0090109 A1
(43) Pub. Date: Mar. 26, 2026

(54) STACKED FET WITH RECESSED CHANNEL TRANSISTORS AT BOTTOM

(71) Applicant: International Business Machines Corporation, Armonk, NY (US)

(72) Inventors: Juntao Li, Cohoes, NY (US); Ruilong Xie, Niskayuna, NY (US); Tao Li, Slingerlands, NY (US); Nicolas Jean Loubet, GUILDERLAND, NY (US); Julien Frougier, Albany, NY (US)

(21) Appl. No.: 18/894,045

(22) Filed: Sep. 24, 2024

(51) Int. Cl. H01L 27/06; H01L 21/822; H01L 21/8234; H01L 29/06; H01L 29/417; H01L 29/423; H01L 29/775; H01L 29/78; H01L 29/786

(52) U.S. Cl. CPC H10D 88/101; H10D 30/43; H10D 30/62; H10D 30/6219; H10D 30/6729; H10D 30/6735; H10D 30/6757; H10D 62/121; H10D 84/0128; H10D 84/0149; H10D 84/0158; H10D 84/038; H10D 88/01

(57) ABSTRACT

Embodiments of the invention disclose semiconductor structures and a method of making the semiconductor structures. According to an embodiment, the semiconductor structure may include a frontside transistor layer having one or more transistors and a backside transistor layer having at least one transistor, the at least one transistor having a recessed channel.

### BACKGROUND

The present invention generally relates to semiconductor structures, and more particularly to a stacked FET with recessed channel transistors at the bottom.

Stacked transistors with independent wiring can increase circuit density, however, forming nanosheets over nanosheets involves high process complexity and an increased chance of yield loss.

### SUMMARY

According to an embodiment of the present invention, a semiconductor structure is provided. The semiconductor structure may include a frontside transistor layer having one or more transistors and a backside transistor layer having at least one transistor, the at least one transistor having a recessed channel.

According to another embodiment of the present invention, a semiconductor structure is provided. The semiconductor structure may include a first transistor layer having at least one transistor, the at least one transistor having a recessed channel, and a second transistor layer having one or more transistors formed above the first transistor layer.

According to another embodiment of the present invention, a method for making a semiconductor structure is provided. The method may include forming a nanosheet (NS) stack over a silicon on insulator (SOI), wherein an etch stop layer divides the SOI into a lower substrate portion and an upper substrate portion, as well as forming nanosheet transistors using the NS stack. The method further includes forming a frontside interconnect for the nanosheet transistors and bonding to a carrier wafer. The method additionally includes flipping the carrier wafer and removing the lower substrate portion up to the etch stop layer. Further, the method includes removing the etch stop layer and forming a recessed channel into the upper substrate portion. Further still, the method further includes forming gate dielectric and gate metal into the recessed channel, as well as forming transistors in the recessed channel by patterning the gate metal, forming gate spacers, and performing low-temperature trench epi. Lastly, the method includes forming a backside contact and a backside interconnect for the transistors in the recessed channel.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIG. 2 is a cross-sectional view of a semiconductor structure 100, according to an embodiment of the invention;

FIG. 3 is a cross-sectional view of the semiconductor structure 100, according to an embodiment of the invention;

FIG. 4 is a cross-sectional view of the semiconductor structure 100, according to an embodiment of the invention;

FIG. 5 is a cross-sectional view of the semiconductor structure 100, according to an embodiment of the invention;

FIG. 6 is a cross-sectional view of the semiconductor structure 100, according to an embodiment of the invention;

FIG. 7 is a cross-sectional view of the semiconductor structure 100, according to an embodiment of the invention;

FIG. 8 is a cross-sectional view of the semiconductor structure 100, according to an embodiment of the invention;

FIG. 9 is a cross-sectional view of the semiconductor structure 100, according to an embodiment of the invention;

FIG. 10 is a cross-sectional view of the semiconductor structure 100, according to an embodiment of the invention;

FIG. 11 is a cross-sectional view of the semiconductor structure 100, according to an embodiment of the invention;

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sublithographic” may refer to a dimension or size less than current dimensions achievable by photolithographic processes, and the term “lithographic” may refer to a dimension or size equal to or greater than current dimensions achievable by photolithographic processes. The sublithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

In the current state of the art, conventional stacked transistors are formed as two layers of similar transistors, for example nanosheet over nanosheet or FinFET over FinFET. While stacked transistors can increase circuit density and both layers may exhibit high performance, forming such stacked transistors involves high process complexity and an increased chance of yield loss.

Not all applications of stacked transistors, however, require two layers of high-performance transistors, and the claimed invention herein discloses stacking different transistors. For example, the claimed invention discloses a structure (and corresponding method) that stacks a frontside layer of nanosheet transistors having high performance on a backside layer of transistors, for example an equivalent to a long channel planar device, suitable for low power applications such as memories. Compared to conventional approaches, the claimed approach provides improvements in terms of lower cost, less process complexity, and higher yield.

According to an embodiment of the present invention, a frontside (or top) transistor layer is formed over a backside (or bottom) transistor layer with simpler/easier device structure and less process complexity. The frontside and backside may be comprised of, for example, CMOS devices. In an embodiment, the frontside layer may include nanosheet transistors and/or FinFETs formed over a backside layer of planar transistors.

Broadly speaking, the process includes forming an NS stack over a silicon on insulator (SOI) wafer, where an SiGe etch stop layer divides the Si substrate into a lower substrate and an upper substrate portion. The process additionally includes forming nanosheet devices using an NS stack above a buried oxide (BOX) layer, as well as forming frontside interconnect and bonding a carrier wafer. Then, after flipping the wafer, the process includes removing lower substrate up to the etch stop layer and removing the etch stop layer. Next, recessed channels are formed into the upper substrate before gate dielectrics and gate metal are formed into the recessed channel. The gate is patterned before forming a spacer and a low-temperature trench epi. Lastly, backside contacts and backside interconnects for the recessed channel transistors are formed.

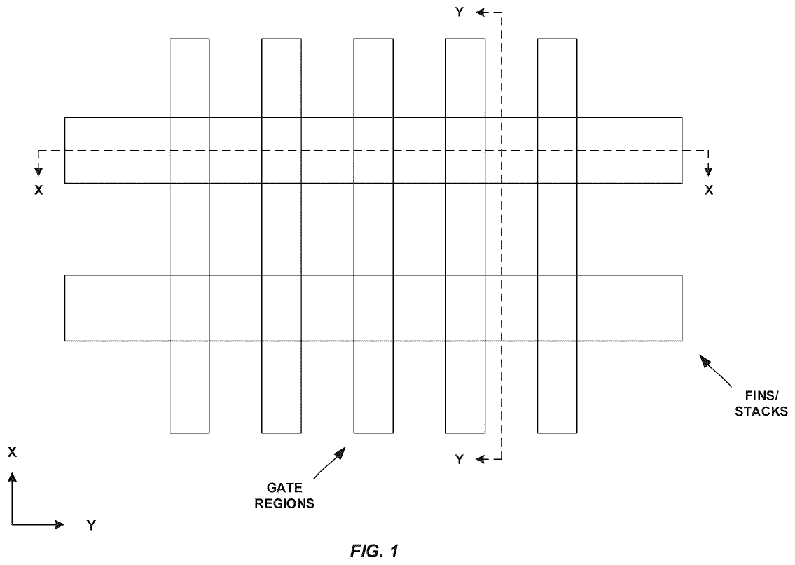

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-11 represent cross section views oriented as indicated in FIG. 1.

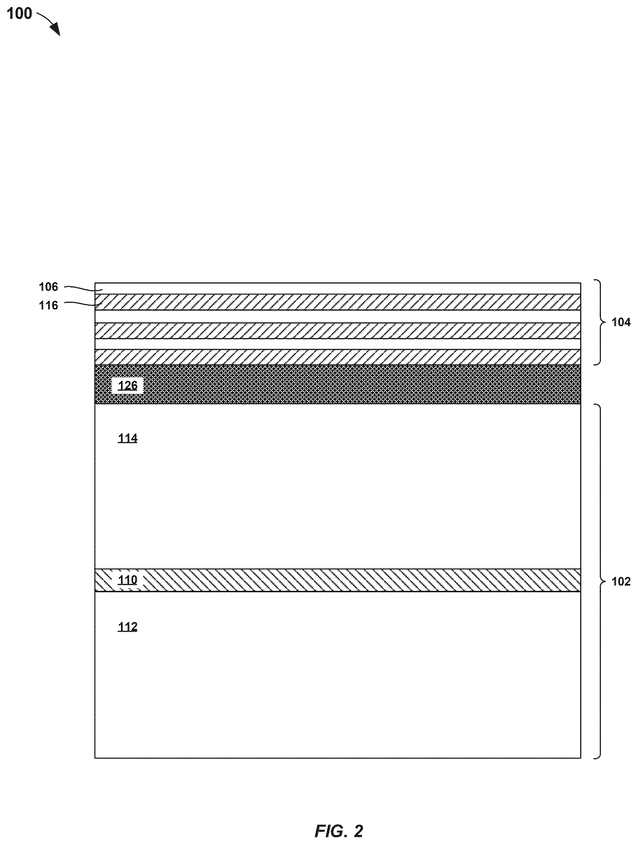

Referring now to FIG. 2, a structure 100 is shown during an intermediate step of a method of fabricating a semiconductor structure, according to an embodiment of the invention.

The structure 100 illustrated in FIG. 2 includes an array of nanosheet stacks 104 formed on a substrate 102 in accordance with known techniques. As illustrated, the nanosheet stacks 104 include a set of raw nanosheets 106 alternately separated by a set of sacrificial sheets 116. For purposes of description, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, the base substrate 112 and the top semiconductor layer 114 may be a layer of material and/or bulk substrate made from any of several known semiconductor materials such as, for example, silicon, germanium, silicon-germanium alloy, and compound (e.g. III-V and II-VI) semiconductor materials. For example, the base substrate 112 and the top semiconductor layer 114 may a bulk Si. Alternatively, the base substrate 112 may be a bulk substrate of Si while the top semiconductor layer 114 may be a layer of Si or SiGe. The base substrate 112 may be referred to herein as a lower substrate portion while the top semiconductor layer 114 may be referred to herein as an upper substrate portion.

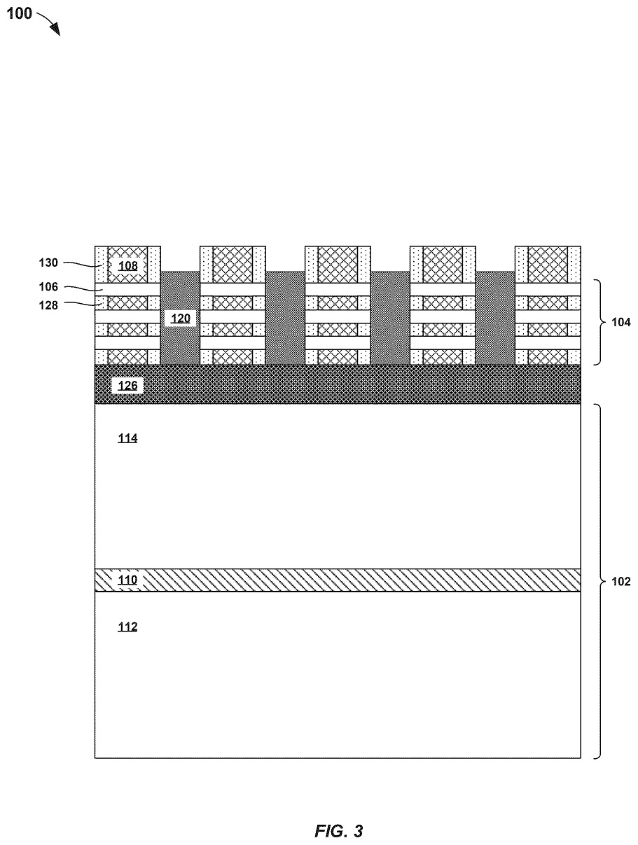

Referring now to FIG. 3, the structure 100 is shown during an intermediate step of a method of fabricating a semiconductor structure, according to an embodiment of the invention.

FIG. 3 illustrates the structure 100 following a series of processing steps performed on the structure 100 of FIG. 2. Each of the nanosheet stacks 104 now include a plurality of silicon channels 106 surrounded by a single gate 108. The structure 100 further includes source drain regions 120 generally arranged between adjacent nanosheet stacks 104, as illustrated.

The source drain regions 120 are formed on top of a buried oxide (BOX) layer 126 according to known techniques. Specifically, the source drain regions 120 are disposed between adjacent nanosheet stacks 104 in direct contact with exposed ends of the silicon channels 106. More specifically, the source drain regions 120 may be epitaxially grown from the exposed ends of the silicon channels 106 according to known techniques.

The structure 100 further includes box layer 126, inner spacers 128, and gate spacers 130.

The box layer 126 is disposed directly beneath the nanosheet stacks 104, separating them from the top semiconductor layer 114. Specifically, for example, a relatively thin layer of silicon nitride is conformally deposited prior to forming the nanosheet stacks 104. In some embodiments, for example, the box layer 126 may be composed of SiN, SiBCN, SiOCN, SiOC, or any other combination of low-k materials. The box layer 126 can provide desired etch selectivity during backside processing.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

The inner spacers 128 are disposed between alternate silicon channels (106), and laterally separate the gates 108 from the source drain regions 120, as illustrated. The inner spacers 128 provide necessary electrical insulation between the gates 108 and the source drain regions 120.

The gate spacers 130 are added to define the channel length and the source drain regions, and ultimately electrically insulate the gates 108 from subsequently formed structures, such as, for example, source drain contact structures. The gate spacers 130 are critical for electrically insulating the gates 108 from the source drain regions 120 or subsequently formed contact structures. In at least one embodiment, the gate spacers 130 include silicon nitride, silicon boron nitride, silicon carbon nitride, silicon boron carbon nitride, or other known equivalents.

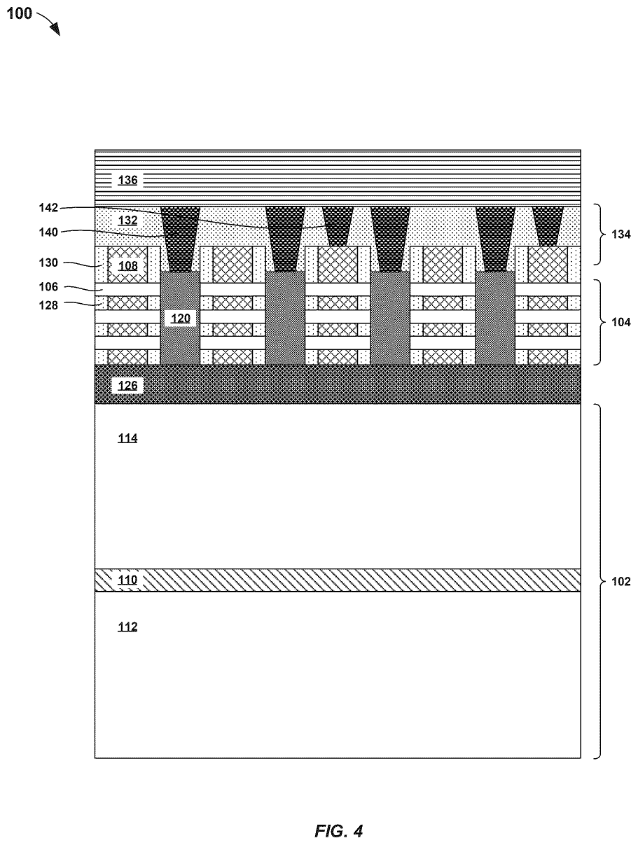

Referring now to FIG. 4, the structure 100 is shown during an intermediate step of a method of fabricating a semiconductor structure, according to an embodiment of the invention.

The structure 100 further includes a dielectric layer 132 directly above and surrounding the source drain regions 120. The dielectric layer 132 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, the dielectric layer 132 is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132.

The structure 100 further includes a middle-of-line 134 and a back-end-of-line 136.

The middle-of-line 134 includes source drain contacts 140 and gate contacts 142 which may be generally referred to as middle-of-line contacts. The source drain contacts 140 and the gate contacts 142 are formed according to known techniques. The back-end-of-line 136 may include vias and metal lines which may be generally referred to as back-end-of-line interconnects. The vias and the metal lines are formed according to known techniques.

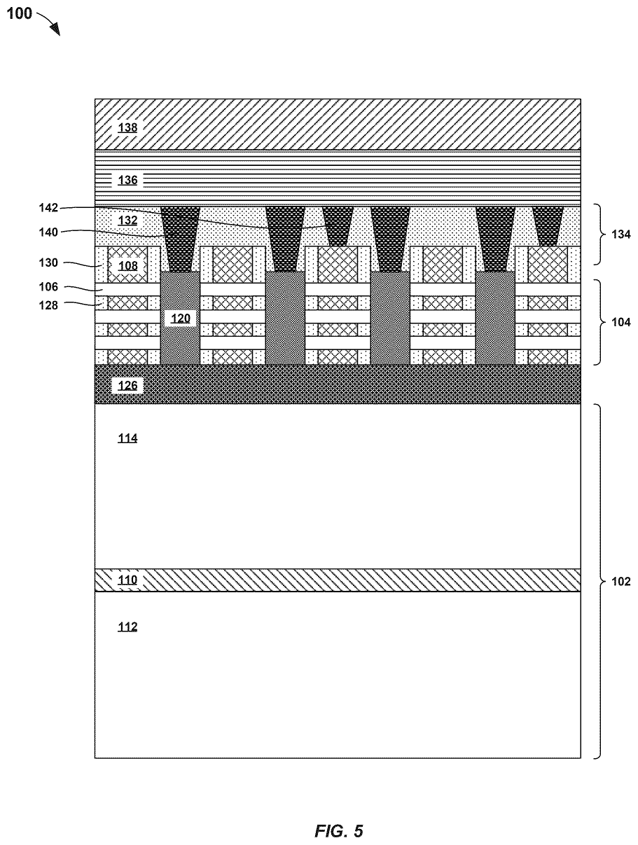

Referring now to FIG. 5, the structure 100 is shown during an intermediate step of a method of fabricating a semiconductor structure, according to an embodiment of the invention.

The structure 100 may further include a carrier wafer 138. The carrier wafer 138 may be bonded to the back-end-of-line 136. The carrier wafer 138 may be formed from any material having appropriate mechanical properties so as to provide stiffness and support to the wafer. The carrier wafer 138 may be used to maneuver the wafer, including turning the wafer over so that the backside of the wafer may be processed. The carrier wafer 138 is secured, such as through a bonding process, to a top surface of the structure 100, according to an embodiment of the invention. The carrier wafer 138 is attached, or removably secured, to the back-end-of-line 136. In general, and not depicted, the carrier wafer 138 may be thicker than the other layers. Temporarily bonding the structure 100 to a thicker carrier provides improved handling and additional support for backside processing of thin wafers. After backside processing described below, the carrier wafer 138 may be de-bonded, or removed, from the structure 100 according to known techniques.

Although only a limited number of components, devices, or structures are shown and described, embodiments of the present invention shall not be limited by any quantity otherwise illustrated or discussed herein.

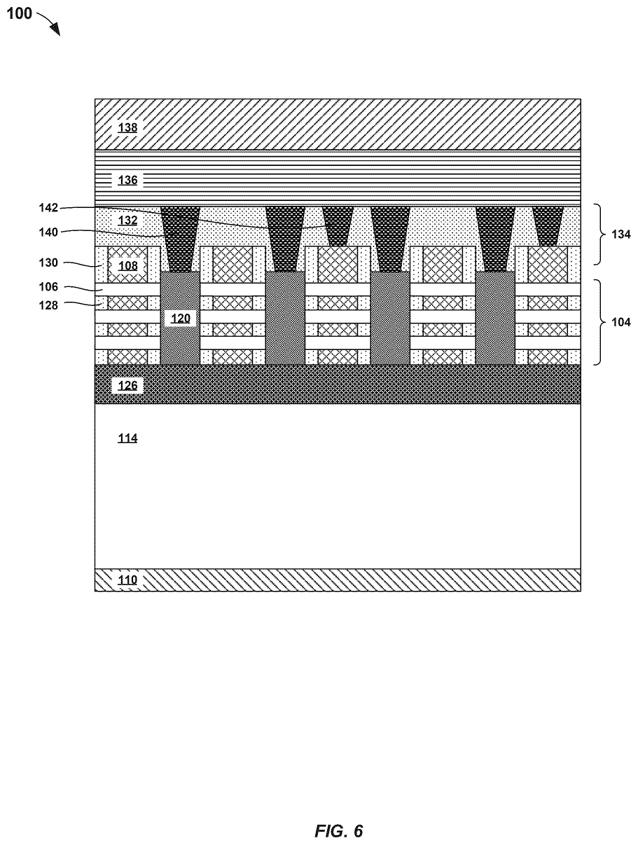

Referring now to FIG. 6, the structure 100 is shown during an intermediate step of a method of fabricating a semiconductor structure, according to an embodiment of the invention.

After flipping the wafer, the base substrate 112 is removed using any appropriately selective etching process that stops at the etch stop layer 110, e.g., an SiGe etch stop layer 110.

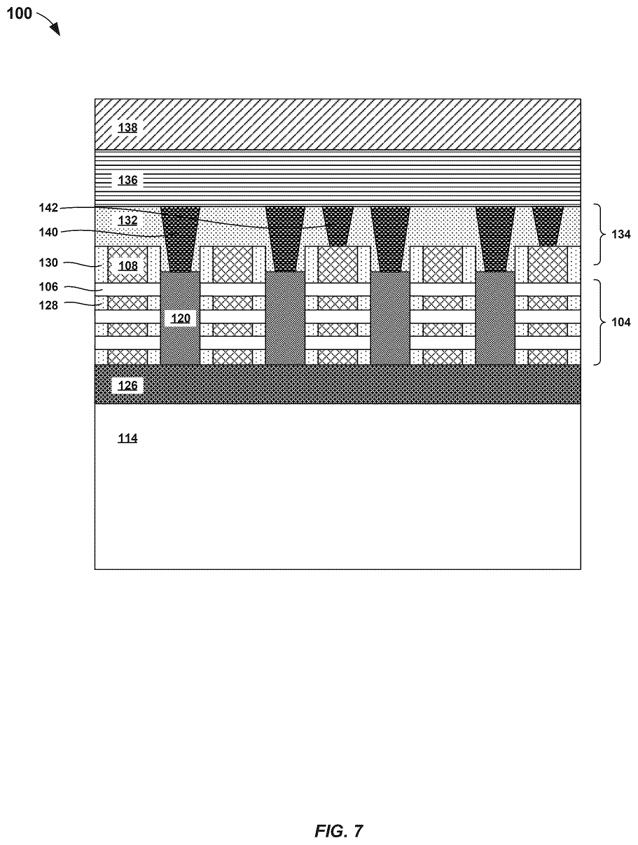

Referring now to FIG. 7, the structure 100 is shown during an intermediate step of a method of fabricating a semiconductor structure, according to an embodiment of the invention.

Next, the etch stop layer 110 is removed. The etch stop layer 110 may be removed using known techniques by any appropriate etch or polishing process to expose the back side of the top semiconductor layer 114.

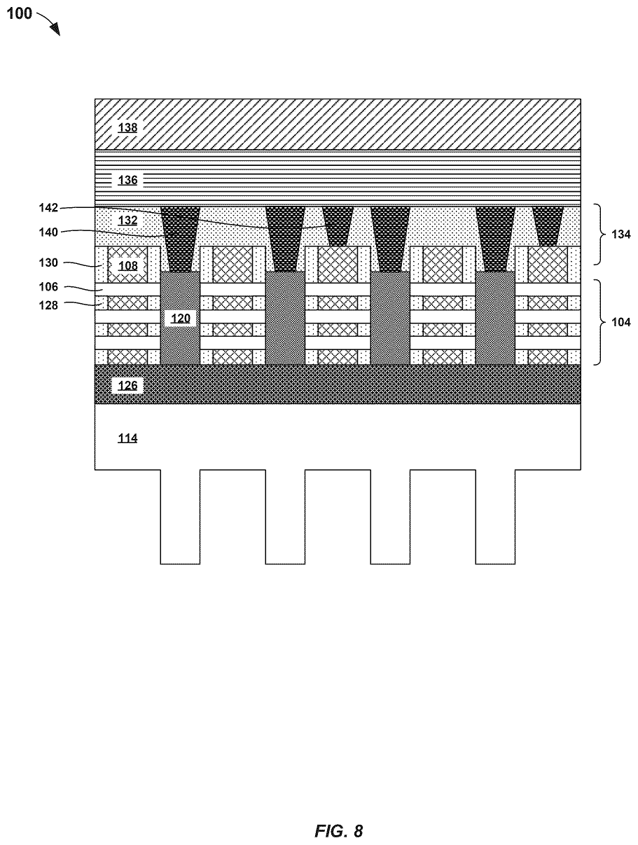

Referring now to FIG. 8, the structure 100 is shown during an intermediate step of a method of fabricating a semiconductor structure, according to an embodiment of the invention.

As illustrated, a conventional lithography and following etch process (such as reactive ion etching (RIE)) are performed to form recessed channel patterning within the top semiconductor layer 114. As will be described in greater detail forthcoming, the recessed channel patterning results in the formation of roughly inverted U-shaped and recessed channels that allows for the subsequent formation of one or more gates within the recessed inverted U-shape. In embodiments, the recessed channel allows for formation of gates having a gate pitch ranging from 40 to 100 nm, and a recess depth of 10 to 60 nm.

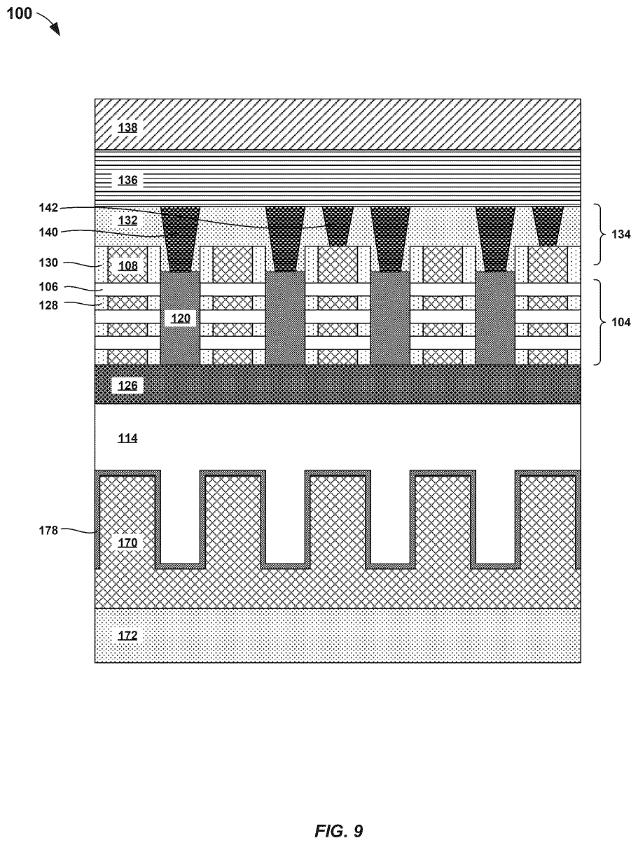

Referring now to FIG. 9, the structure 100 is shown during an intermediate step of a method of fabricating a semiconductor structure, according to an embodiment of the invention.

Next, gate dielectrics 178, gate metals 170, and gate dielectric caps 172 are formed. As illustrated, the gate dielectrics 178 are first conformally deposited on the patterned surface of the top semiconductor layer 114. The gate dielectrics 178 may be formed from any appropriate insulating material, but it is specifically contemplated that the gate dielectrics 178 will be a high-k dielectric material. A high-k dielectric material is a material having a dielectric constant k that is higher than that of silicon dioxide. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric material may further include dopants such as lanthanum and aluminum.

In one embodiment, the dielectric material is conformally deposited using a highly conformal deposition process, such as atomic layer deposition (ALD), to ensure that the recessed area is sufficiently filled with dielectric material. Other deposition methods such as chemical vapor deposition (CVD), physical vapor deposition (PVD) and PVD can be used to deposit a highly conformal layer of dielectric material to fill the recesses area. Next, the gate metals 170 are deposited onto the gate dielectrics 178 to fill and form a layer on top of the patterned surface of the top semiconductor layer 114. The gate structure may further comprise a gate work function setting layer (not shown) between the gate dielectric and the gate conductor. The gate work function setting layer can be a metallic compound, including but not limited to: (i) nitrides (e.g., titanium nitride (TiN), hafnium nitride (HfN), hafnium silicon nitride (HfSiN), tantalum nitride (TaN), tantalum silicon nitride (TaSiN), tungsten nitride (WN), molybdenum nitride (MoN), and niobium nitride (NbN)); (ii) carbides (e.g., titanium carbide (TiC), titanium aluminum carbide (TiAlC), tantalum carbide (TaC), and hafnium carbide (HfC)); and (iii) combinations thereof. The deposition techniques include, but not limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), sputtering, and/or plating. Lastly, gate dielectric caps 172 are conformally deposited onto the gate metals 170.

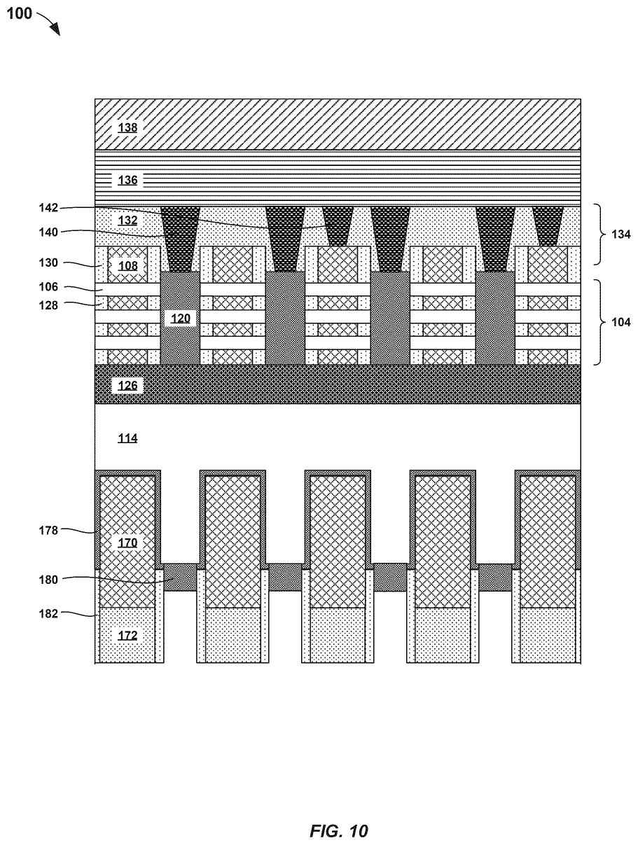

Referring now to FIG. 10, the structure 100 is shown during an intermediate step of a method of fabricating a semiconductor structure, according to an embodiment of the invention.

Here, patterning is performed on the gate metals 170 and the gate dielectric caps 172 to form gates. In addition, gate spacers 182 are formed on either side of at least a portion of the gate metals 170 and the gate dielectric caps 172. The gate spacers 182 can be formed of silicon nitride, silicoboron carbonitride, silicon carbonitride, silicon carbon oxynitride, or any other type of dielectric material (e.g., a dielectric material having a dielectric constant k of less than 5) appropriate to the role of forming an insulating gate sidewall spacer. The gate spacers 182 can be conformally deposited using a highly conformal deposition process, such as atomic layer deposition (ALD), followed by an etch back process (RIE) to remove the spacer material on horizontal surface and form sidewall spacers as shown in FIG. 10. Lastly, as illustrated, source drain regions 180 are formed in between the gate spacers 182 on an opposite side of the gate spacers 182 than the gate metals 170 and the gate dielectric caps 172.

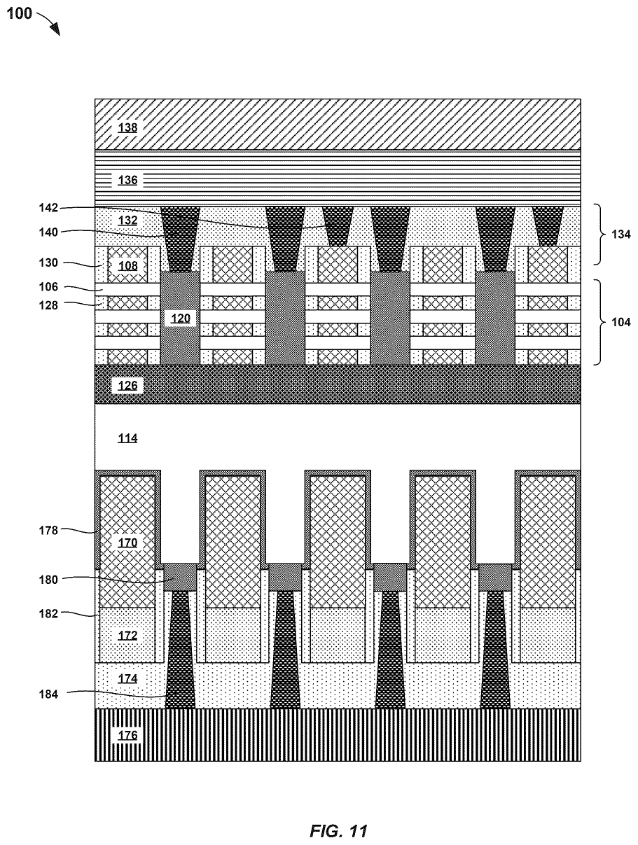

Referring now to FIG. 11, the structure 100 is shown during an intermediate step of a method of fabricating a semiconductor structure, according to an embodiment of the invention.

Next, a backside interlayer dielectric (BILD) 174 is deposited. The BILD 174 material, includes, but is not limited to, SiO₂, LTO, HTO, FOX or some other dielectric. The BILD 174 can be deposited using deposition techniques including, but not limited to, CVD, PECVD, RFCVD, PVD, ALD, MLD, MBD, PLD, and/or LSMCD, sputtering, and/or plating.

Planarization, for example CMP, can be performed to remove excess material from the BILD 174 and planarize the resulting structure. Further, backside contact 184 is formed before forming a backside interconnect 176.

It should be noted that while the structure 100 is configured to vertically align the gates 108 and the gate metals 170, in other embodiments, the gates 108 may be configured to vertically misalign with the gate metals 170. Similarly, while the structure 100 is configured to vertically align the source drain regions 120 and the source drain regions 180, in other embodiments, the source drain regions 120 may be configured to vertically misalign with the source drain regions 180.

Returning to FIG. 11, and according to an embodiment, the structure 100 includes a frontside transistor layer having one or more transistors and a backside transistor layer having at least one transistor, the at least one transistor having a recessed channel.

With continued reference to FIG. 11, and according to an embodiment, the recessed channel is recessed into a silicon layer.

With continued reference to FIG. 11, and according to an embodiment, the recessed channel is formed in an inverted U-shape.

With continued reference to FIG. 11, and according to an embodiment, the frontside transistor layer is isolated from the backside transistor layer by a buried oxide layer.

With continued reference to FIG. 11, and according to an embodiment, the at least one transistor is a planar transistor.

With continued reference to FIG. 11, and according to an embodiment, the one or more transistors are nanosheet transistors or FinFETs.

With continued reference to FIG. 11, and according to an embodiment, the at least one transistor is a planar transistor, and the one or more transistors are nanosheet transistors or FinFETs.

With continued reference to FIG. 11, and according to an embodiment, two or more of the at least one transistor are arranged side-by-side.

With continued reference to FIG. 11, and according to an embodiment, a channel of the at least one transistor is at a height above a source drain region of the at least on transistor.

With continued reference to FIG. 11, and according to an embodiment, a channel of the at least one transistor is at a height above a gate of the at least one transistor.

With continued reference to FIG. 11, and according to an embodiment, one or more gates of the one or more transistors align with at least one gate of the at least one transistor.

With continued reference to FIG. 11, and according to an embodiment, the recessed channel is conformally lined by one or more backside gate dielectrics.

With continued reference to FIG. 11, and according to an embodiment, the backside transistor layer includes one or more backside gate spacers to isolate one or more backside gates from one or more backside source drain regions.

With continued reference to FIG. 11, and according to an embodiment, the one or more backside gate spacers are vertically aligned with a vertical portion of the one or more backside gate dielectrics.

With continued reference to FIG. 11, and according to an embodiment, the one or more backside gate dielectrics are formed in an inverted U-shaped and conform to the recessed channel.

With continued reference to FIG. 11, and according to an embodiment, a height of the one or more backside gates is higher than a vertical portion of the one or more backside gate spacers.

With continued reference to FIG. 11, and according to an embodiment, the structure 100 includes a first transistor layer having at least one transistor, the at least one transistor having a recessed channel, and a second transistor layer having one or more transistors formed above the first transistor layer.

With continued reference to FIG. 11, and according to an embodiment, the recessed channel is recessed into a silicon layer.

With continued reference to FIG. 11, and according to an embodiment, the first transistor layer is isolated from the second transistor layer by a buried oxide layer.

With continued reference to FIG. 11, and according to an embodiment, a method of forming a semiconductor structure comprises forming a nanosheet (NS) stack over a silicon on insulator (SOI), wherein an etch stop layer divides the SOI into a lower substrate portion and an upper substrate portion, as well as forming nanosheet transistors using the NS stack. The method further includes forming a frontside interconnect for the nanosheet transistors and bonding to a carrier wafer. The method additionally includes flipping the carrier wafer and removing the lower substrate portion up to the etch stop layer. Further, the method includes removing the etch stop layer and forming a recessed channel into the upper substrate portion. Further still, the method further includes forming gate dielectric and gate metal into the recessed channel, as well as forming transistors in the recessed channel by patterning the gate metal, forming gate spacers, and performing low-temperature trench epi. Lastly, the method includes forming a backside contact and a backside interconnect for the transistors in the recessed channel.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a frontside transistor layer having one or more transistors; and
a backside transistor layer having at least one transistor, the at least one transistor having a recessed channel.

2. The semiconductor structure of claim 1, wherein the recessed channel is recessed into a silicon layer.

3. The semiconductor structure of claim 1, wherein the recessed channel is formed in an inverted U-shape.

4. The semiconductor structure of claim 1, wherein the frontside transistor layer is isolated from the backside transistor layer by a buried oxide layer.

5. The semiconductor structure of claim 1, wherein the at least one transistor is a planar transistor.

6. The semiconductor structure of claim 1, wherein the one or more transistors are selected from a group consisting of nanosheet transistors and FinFETs.

7. The semiconductor structure of claim 1, wherein the at least one transistor is a planar transistor, and wherein the one or more transistors are selected from a group consisting of nanosheet transistors and FinFETs.

8. The semiconductor structure of claim 1, wherein two or more of the at least one transistor are arranged side-by-side.

9. The semiconductor structure of claim 1, wherein a channel of the at least one transistor is at a height above a source drain region of the at least on transistor.

10. The semiconductor structure of claim 1, wherein a channel of the at least one transistor is at a height above a gate of the at least one transistor.

11. The semiconductor structure of claim 1, wherein one or more gates of the one or more transistors align with at least one gate of the at least one transistor.

12. The semiconductor structure of claim 1, wherein the recessed channel is conformally lined by one or more backside gate dielectrics.

13. The semiconductor structure of claim 12, wherein the backside transistor layer includes one or more backside gate spacers to isolate one or more backside gates from one or more backside source drain regions.

14. The semiconductor structure of claim 13, wherein the one or more backside gate spacers are vertically aligned with a vertical portion of the one or more backside gate dielectrics.

15. The semiconductor structure of claim 14, wherein the one or more backside gate dielectrics are formed in an inverted U-shaped and conform to the recessed channel.

16. The semiconductor structure of claim 15, wherein a height of the one or more backside gates is higher than a vertical portion of the one or more backside gate spacers.

17. A semiconductor structure comprising:
a first transistor layer having at least one transistor, the at least one transistor having a recessed channel; and
a second transistor layer having one or more transistors formed above the first transistor layer.

18. The semiconductor structure of claim 17, wherein the recessed channel is recessed into a silicon layer.

19. The semiconductor structure of claim 17, wherein the first transistor layer is isolated from the second transistor layer by a buried oxide layer.

20. A method of forming a semiconductor structure comprising:
forming a nanosheet (NS) stack over a silicon on insulator (SOI), wherein an etch stop layer divides the SOI into a lower substrate portion and an upper substrate portion;
forming nanosheet transistors using the NS stack;
forming a frontside interconnect for the nanosheet transistors;
bonding to a carrier wafer;
flipping the carrier wafer;
removing the lower substrate portion up to the etch stop layer;
removing the etch stop layer;
forming a recessed channel into the upper substrate portion;
forming gate dielectric and gate metal into the recessed channel;
forming transistors in the recessed channel by patterning the gate metal, forming gate spacers, and performing low-temperature trench epi; and
forming a backside contact and a backside interconnect for the transistors in the recessed channel.
